(19) United States
(12) Patent Application Publication
(10) Pub. No.: US 2017/0354055 A1
(43) Pub. Date: Dec. 7, 2017

(54) Quick Release Device for a Slide Track

(71) Applicant: Kunshan Lemtech SlideTechnology Co., Ltd., Kunshan City (CN)

(72) Inventor: Chi-Feng Hsu, New Taipei City (TW)

(21) Appl. No.: 15/172,186

(22) Filed: Jun. 3, 2016

(51) Int. Cl. H05K 7/14

(52) U.S. Cl. CPC H05K 7/1489

(57) ABSTRACT

A quick release device for a slide track includes a frame having an abutment section. A positioning seat is fixed to the frame and has a fixing section located adjacent to the abutment section and a first sleeve. A plurality of positioning devices is mounted to the fixing section and extends beyond the abutment section. A retaining member includes a base having first and second sides. At least one arm extends from the first side of the base and includes a hook. A second sleeve and a limiting portion are formed on the second side of the base. An axle is pivotably received in the first sleeve and the second sleeve to pivotably connect the retaining member to the positioning seat. An elastic element is pivotably mounted to the axle and includes two tangs respectively attached to the positioning seat and the limiting portion of the retaining member.

### BACKGROUND OF THE INVENTION

The present invention relates to a quick release device for a slide track and, more particularly, to a quick release device including a retaining device having a hook member pivotable relative to a frame to permit rapid assembly and disassembly of the frame and a rack of a server.

When installing a slide track on a rackmount server system, the slide track is connected to a frame which is coupled to a rack of the server system. A plurality of sets of slide tracks and frames can be disposed on the rack and arranged in a vertical direction. However, it is impossible to disassemble one of the plurality of sets of slide tracks and frames from a top side or a bottom side thereof. A mechanism permitting disassembly from a front side of the rack is complicated and inconvenient to assemble and use.

Thus, a need exists for a novel device that mitigates and/or obviates the above disadvantages.

### BRIEF SUMMARY OF THE INVENTION

The primary objective of the present invention is to provide a quick release device including a retaining device having a hook member biased to pivot in a desired direction relative to a frame, such that when the frame is positioned by a positioning device to a rack of a server, the frame can be rapidly assembled to and disassembled from the rack, providing convenience use and having a simple structure.

To fulfill the above objective, the present invention provides a quick release device for a slide track including a frame having a positioning portion. An abutment section extends transversely from a side of the positioning portion. A positioning seat includes a connecting portion fixed to the positioning portion of the frame. The connecting portion includes a first side having a fixing section located adjacent to the abutment section. The connecting portion further includes a second side having a first sleeve. A plurality of positioning devices is mounted to the fixing section of the positioning seat and extends beyond the abutment section of the frame. A retaining device includes a retaining member, an elastic element, and an axle. The retaining member includes a base having first and second sides. At least one arm extends from the first side of the base and includes a hook. A second sleeve and a limiting portion are formed on the second side of the base. The axle is pivotably received in the first sleeve of the positioning seat and the second sleeve to pivotably connect the retaining member to the positioning seat. The abutment section of the frame is located between the hook and the positioning seat. The elastic element is pivotably mounted to the axle and includes first and second tangs respectively attached to the connecting portion of the positioning seat and the limiting portion of the retaining member.

The hook of the engagement device can include an inclined guiding face.

The elastic element can be a torsion spring and can include a body and the first and second tangs extending from two sides of the body. The connecting portion can include a fixing plate. The limiting portion of the retaining member can include a fixing groove. The first and second tangs are respectively coupled to the fixing plate and the fixing groove.

Each of the plurality of positioning devices can include a positioning rod having a first end fixed to the fixing section of the positioning seat and a second end. Each of the plurality of positioning devices can further include a limiting rod connected to the second end of the positioning rod and a spring mounted between the positioning rod and the limiting rod. The limiting rod extends beyond the abutment section of the frame.

The limiting rod can include a first section and a second section. The first section has an outer diameter smaller than an outer diameter of the second section. The second section is located between the first section and the first end of the positioning rod.

The present invention will become clearer in light of the following detailed description of illustrative embodiments of this invention described in connection with the drawings.

### DESCRIPTION OF THE DRAWINGS

FIG. 1 is a perspective view of a quick release device for a slide track of an example according to the present invention.

FIG. 2 is another perspective view of the quick release device of FIG. 1.

FIG. 3 is a partly-exploded perspective view of the quick release device of FIG. 2.

FIG. 4 is a perspective view illustrating assembly of the quick release device on a rack.

FIG. 5 is a side view of the quick release device and the rack of FIG. 4, illustrating detachment of the quick release device from the rack.

FIG. 6 is another perspective view, partly-cutaway, of a quick release device of another example according to the present invention and a rack after assembly.

FIG. 7 is a side view of the quick release device and the rack of FIG. 6.

### DETAILED DESCRIPTION OF THE INVENTION

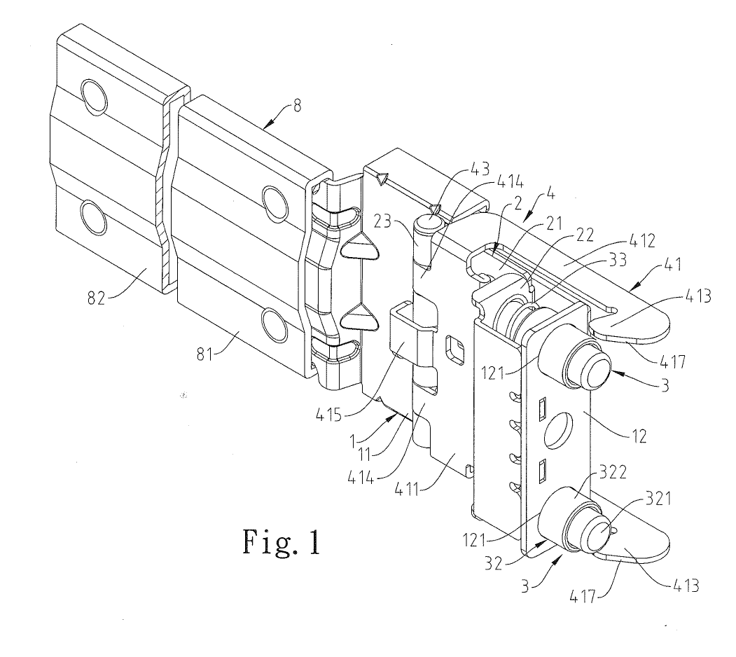

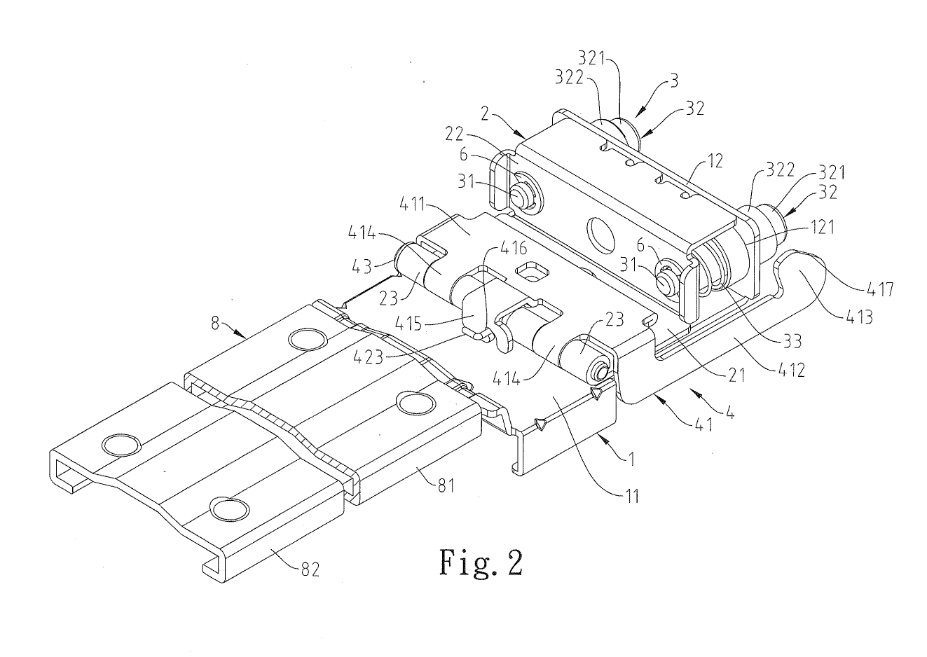

With reference to FIGS. 1-3, a quick release device for a slide track of an example according to the present invention includes a frame 1, a positioning seat 2, a plurality of positioning devices 3, and a retaining device 4. The frame 1 includes a positioning portion 11. An abutment section 12 extends transversely from a side of the positioning portion 11 and includes a plurality of limiting holes 121.

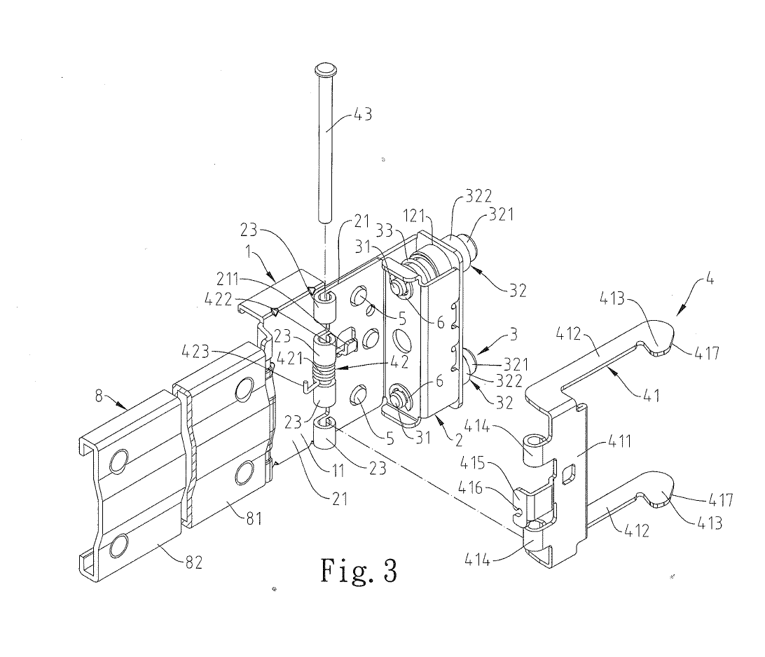

The positioning seat 2 includes a connecting portion 21 fixed to the positioning portion 11 of the frame 1 by fasteners 5. The connecting portion 21 includes a first side having a fixing section 22 located adjacent to the abutment section 12. The connecting portion 21 further includes a second side having a first sleeve 23. A fixing plate 211 is formed on the connecting portion 21 (see FIG. 3).

The positioning devices 3 are mounted to the fixing section 22 of the positioning seat 2 and extend beyond the abutment section 12 of the frame 1. In this example, each positioning device 3 includes a positioning rod 31 having a first end fixed by a retaining ring 6 to the fixing section 22 of the positioning seat 2. Each positioning device 3 further includes a limiting rod 32 is connected to a second end of the positioning rod 31 and a spring 33 mounted between the positioning rod 31 and the limiting rod 32. The limiting rod 32 includes a first section 321 and a second section 322. An outer diameter of the first section 321 is smaller than an outer diameter of the second section 322. The second section 322 is located between the first section 321 and the first end of the positioning rod 31. The limiting rod 32 extends beyond the abutment section 12 of the frame 1 via a corresponding limiting hole 121.

The retaining device 4 includes a retaining member 41, an elastic element 42, and an axle 43. The retaining member 41 includes a base 411 having first and second sides. At least one arm 412 extends from the first side of the base 411 and includes a hook 413. In this example, two arms 412 extend from the first side of the base 411 in the same direction, and a hook 413 is formed on the distal end of each arm 412 and has an inclined guiding face 417. A second sleeve 414 and a limiting portion 415 are formed on the second side of the base 411. The limiting portion 415 includes a fixing groove 416. In this example, the elastic element 42 is a torsion spring and includes a body 421 and first and second tangs 422 and 423 extending from two sides of the body 421. The first and second tangs 422 and 423 are respectively coupled to the fixing plate 211 and the fixing groove 416.

In assembly of the retaining device 4 and the positioning seat 2, the body 421 of the elastic element 42, the second sleeve 414 of the retaining member 41, and the first sleeve 23 of the positioning seat 2 are aligned with each other, and the axle 43 extends through the first sleeve 23, the body 421, and the second sleeve 414 to pivotably connect the retaining member 41 to the positioning seat 2. The abutment section 12 of the frame 1 is located between the hook 413 and the positioning seat 2. The first and second tangs 422 and 423 of the elastic element 42 are respectively coupled to the fixing plate 211 and the fixing groove 416. The elasticity of the elastic element 42 biases the limiting portion 415 and the fixing groove 416 of the retaining member 41 towards the positioning portion 11, such that the hooks 413 are pivotable towards the abutment section 12 under the bias of the elastic element 42.

With reference to FIGS. 3-5, a rack 7 for a server (not shown) extends in a vertical direction and includes a plurality of positioning holes 71. In assembly with the rack 7, the limiting rod 32 of each positioning device 3 extends from a side of the rack 7 through a corresponding positioning hole 71 in the rack 7 to the other side of the rack 7. In this example, each positioning hole 71 has a diameter corresponding to the outer diameter of the second section 322 of the limiting rod 32 to retain the second section 322 in the positioning hole 71. When the limiting rod 32 extends through the positioning hole 71 of the rack 7, the inclined guiding face 417 of the retaining member 41 abuts a lateral side of the rack 7, such that the hooks 413 of the retaining member 41 pivot away from the abutment section 12. After the inclined guiding face 417 has passed through the rack 7, the elasticity of the elastic element 42 pivot the hooks 413 to a position adjacent to the abutment section 12 and the other side of the rack 7, accomplishing the assembly.

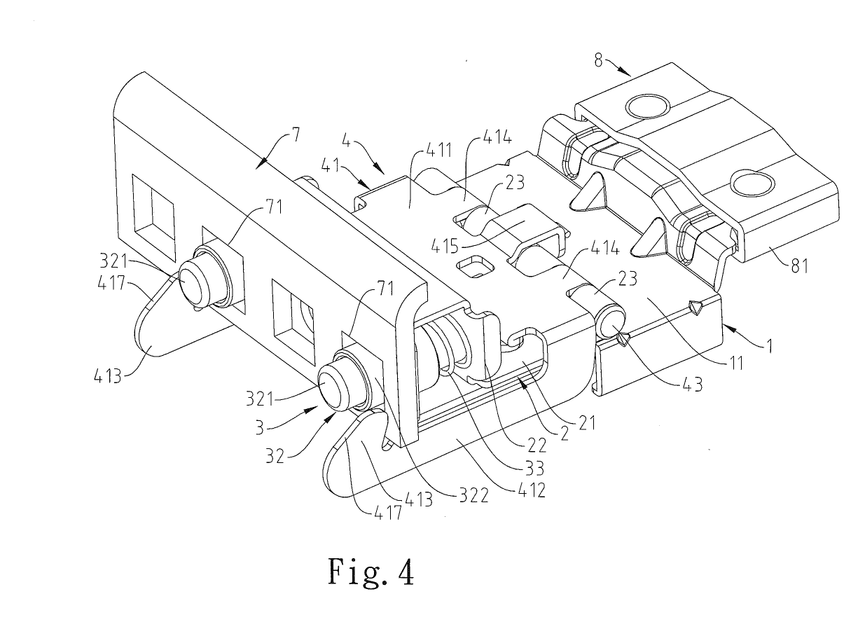

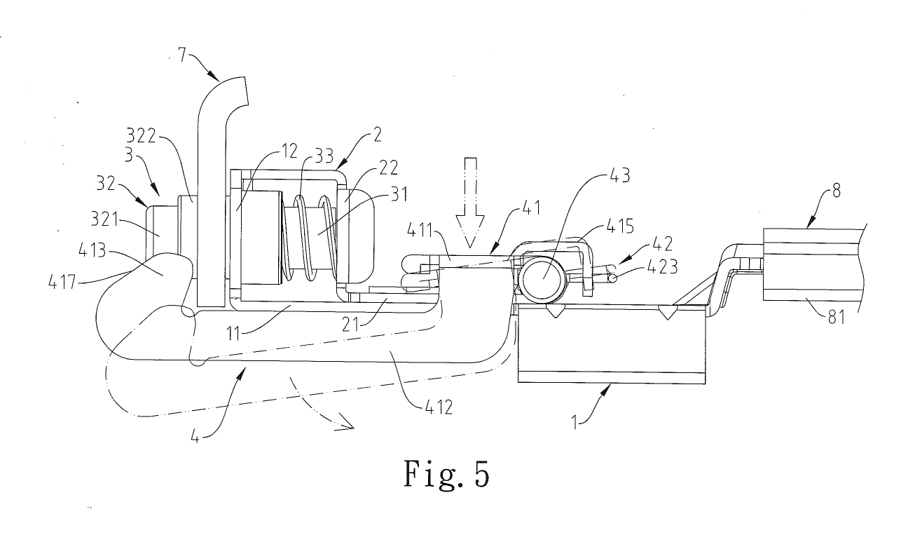

When it is desired to disassemble the quick release device from the rack 7, a user can directly press the base 411 of the retaining member 41 or push the hooks 413 away, causing the retaining member 41 to pivot relative to the second sleeve 414 and the axle 43. Thus, the hooks 413 pivot away from the abutment section 12 of the frame 1 (see FIGS. 4 and 5). After the hooks 413 have left the abutment section 12 of the frame 1 and the other side of the rack 7, the limiting rod 32 of each positioning device 3 can be pulled out of a corresponding positioning hole 71 of the rack 7, accomplishing the disassembly.

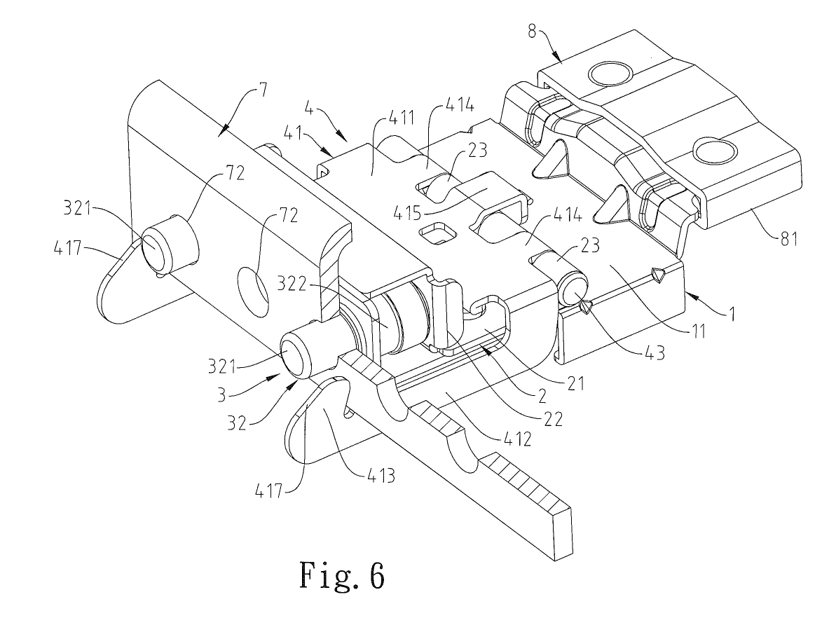

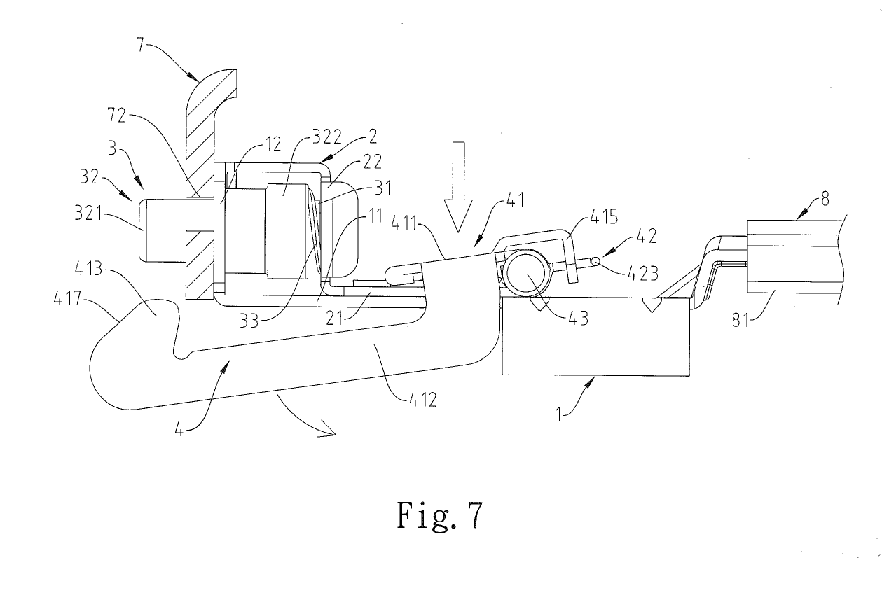

With reference to FIGS. 3, 6, and 7, in a case that the positioning holes 72 of the rack 7 have a smaller diameter equal to the outer diameter of the first section 321 of each limiting rod 32, when each limiting rod 32 is inserted through a corresponding positioning hole 72 of the rack 7, the first section 321 is positioned in the positioning hole 72. Assembly and disassembly of the retaining member 41 of the retaining device 4 and the rack 7 are identical to the first example.

With reference to FIG. 1, the quick release device is mounted to an end 81 of a telescopic track 8, and another quick release device is mounted to the other end 82 of the telescopic track and can be coupled with another rack parallel to and spaced from the rack 7 shown in FIG. 4. The another quick release device does not have to include the retaining device 4 and can be of another type if desired. A fixed track (not shown) of a slide track (not shown) of a server (not shown) can be fixed to a side of the telescopic track 8.

Although specific embodiments have been illustrated and described, numerous modifications and variations are still possible without departing from the scope of the invention. The scope of the invention is limited by the accompanying claims.

1. A quick release device for a slide track, comprising:
a frame including a positioning portion, with an abutment section extending transversely from a side of the positioning portion;
a positioning seat including a connecting portion fixed to the positioning portion of the frame, with the connecting portion including a first side having a fixing section located adjacent to the abutment section, and with the connecting portion further including a second side having a first sleeve;
a plurality of positioning devices mounted to the fixing section of the positioning seat and extending beyond the abutment section of the frame; and
a retaining device including a retaining member, an elastic element, and an axle, with the retaining member including a base having first and second sides, with at least one arm extending from the first side of the base and including a hook, with a second sleeve and a limiting portion formed on the second side of the base, with the axle pivotably received in the first sleeve of the positioning seat and the second sleeve to pivotably connect the retaining member to the positioning seat, with the abutment section of the frame located between the hook and the positioning seat, and with the elastic element pivotably mounted to the axle and including first and second tangs respectively attached to the connecting portion of the positioning seat and the limiting portion of the retaining member.

2. The quick release device for a slide track as claimed in claim 1, wherein the hook of the engagement device includes an inclined guiding face.

3. The quick release device for a slide track as claimed in claim 1, with the elastic element being a torsion spring and including a body and the first and second tangs extending from two sides of the body, with the connecting portion including a fixing plate, with the limiting portion of the retaining member including a fixing groove, and with the first and second tangs respectively coupled to the fixing plate and the fixing groove.

4. The quick release device for a slide track as claimed in claim 1, with each of the plurality of positioning devices including a positioning rod having a first end fixed to the fixing section of the positioning seat and a second end, with each of the plurality of positioning devices further including a limiting rod connected to the second end of the positioning rod and a spring mounted between the positioning rod and the limiting rod, and with the limiting rod extending beyond the abutment section of the frame.

5. The quick release device for a slide track as claimed in claim 4, with the limiting rod including a first section and a second section, with the first section having an outer diameter smaller than an outer diameter of the second section, and with the second section located between the first section and the first end of the positioning rod.
